(19) United States
(12) Patent Application Publication
(10) Pub. No.: US 2017/0179429 A1
(43) Pub. Date: Jun. 22, 2017

(54) ARRAY SUBSTRATES, MANUFACTURING METHODS THEREOF AND DISPLAY PANELS

(71) Applicants: SHANGHAI TIANMA AM-OLED CO., LTD., Shanghai (CN); TIANMA MICRO-ELECTRONICS CO., LTD., Shenzhen (CN)

(72) Inventors: Jian JIN, Shanghai (CN); Congyi SU, Shanghai (CN)

(21) Appl. No.: 15/195,182

(22) Filed: Jun. 28, 2016

(30) Foreign Application Priority Data
Dec. 21, 2015 (CN) 201510967220.6

(51) Int. Cl. H01L 51/52; H01L 51/56

(52) U.S. Cl. CPC H01L 51/5253; H01L 51/56

(57) ABSTRACT

An array substrate, a manufacturing method thereof and a display panel including the array substrate are provided. The array substrate includes a display region, a border region and a gap region between the display region and the border region, and includes: a first substrate; an OLED display unit on a surface of the display region; a barrier structure on a surface of the gap region; and a protective layer covering the OLED display unit. A boundary of the protective layer and that of the barrier structure toward the display region are connected; and a circuit board on a surface of the border region. With the array substrate, a problem that the protective layer located on a surface of the OLED display unit extends to the border region to cause a negative influence on a subsequent binding process for the circuit board is solved.

### CROSS REFERENCES OF RELATED APPLICATION

The present application claims the priority to Chinese Patent Application No. 201510967220.6, titled “ARRAY SUBSTRATES, MANUFACTURING METHODS THEREOF AND DISPLAY PANELS”, filed on Dec. 21, 2015 with the State Intellectual Property Office of the People's Republic of China, which is incorporated herein by reference in its entirety.

### TECHNICAL FIELD

The present disclosure relates to the technical field of display, and in particular to an array substrate, a manufacturing method thereof and a display panel including the array substrate.

### BACKGROUND

As shown in FIG. 1, in the conventional technology, an OLED display device includes a display region A and a border region B. An OLED display unit 01 is arranged in the display region A, a circuit board (which is not illustrated in the figure) is arranged in the border region B, and the circuit board is configured to provide a drive signal for the OLED display unit 01 to ensure that the OLED display unit 01 operates properly. The OLED display unit 01 is easy to suffer from oxidation due to moisture or oxygen in air. Therefore, in a process of manufacturing the OLED display device, the OLED display unit 01 is usually formed at a location on a surface of a substrate 02 corresponding to the display region A first; then, a protective layer 03 is formed on a side of the OLED display unit 01 away from the substrate 02, so as to protect the OLED display unit 01 from the moisture or the oxygen in the air; and finally, the circuit board is bound to a location on a surface of the substrate 02 corresponding to the border region B, to provide the drive signal for the OLED display unit 01 in the display region.

In practice, when a reticle 04 is placed at a location on a surface of the substrate 02 corresponding to the border region B and the protective layer 03 is then formed on the side of the OLED display unit 01 away from the substrate 02 by using the reticle 04 as a mask, there is inevitably a gap between the reticle 04 and the substrate 02. Hence, the protective layer 03 not only covers the display region A but may also extend to the border region B through the gap between the reticle 04 and the substrate 02, which causes a negative influence on subsequent processes such as a binding process for the circuit board.

### BRIEF SUMMARY OF THE INVETION

The following technical solutions are provided according to the embodiments of the present disclosure.

An array substrate, including a display region, a border region surrounding the display region and a gap region located between the display region and the border region, is provided. The array substrate includes a first substrate; an OLED display unit, located on a surface of a display region on a first side of the first substrate; a barrier structure, located on a surface of a gap region on the first side of the first substrate; a protective layer covering the OLED display unit, located on the first side of the first substrate, where a boundary of the protective layer and a boundary of the barrier structure toward the display region are connected; and a circuit board, located on a surface of the border region on the first side of the first substrate.

A display panel is provided, which includes the above array substrate.

A method for manufacturing an array substrate including a display region, a border region surrounding the display region and a gap region located between the display region and the border region, is provided, which includes:

providing a first substrate;

forming an OLED display unit on a surface of a display region on a first side of the first substrate;

forming a barrier structure on a surface of a gap region on the first side of the first substrate;

placing a reticle on a surface of the border region on the first side of the first substrate and a surface of the barrier structure;

forming a protective layer covering the OLED display unit, on the first side of the first substrate, by using the reticle as a mask, where a boundary of the protective layer and a boundary of the barrier structure toward the display region are connected; and

removing the reticle, and binding a circuit board to the surface of the border region on the first side of the first substrate.

Compared with the conventional technology, the above technical solutions have one or more advantages as follows.

For the array substrate according to the embodiments of the present disclosure, a surface of the array substrate includes the display region, the border region and the gap region located between the display region and the border region. In addition to the OLED display unit located in the display region and the circuit board located in the border region, the array substrate further includes the barrier structure located in the gap region. The barrier structure is located between the OLED display unit and the circuit board. Hence, when the protective layer is formed on a surface of the OLED display unit away from the first substrate by using the reticle, the barrier structure may be used to fill a gap between the reticle and the first substrate, thereby preventing the protective layer from extending to the border region, and ensuring that the protective layer is located only in the display region or partially extends to the gap region without extending to the border region. Therefore, the problem in the conventional technology that the protective layer located on the surface of the OLED display unit extends to the border region to cause a negative influence on the subsequent processes such as the binding process for the circuit board is solved.

### BRIEF DESCRIPTION OF THE DRAWINGS

In order to more clearly illustrate technical solutions in embodiments of the present disclosure or in the conventional technology, drawings used in the description of the embodiments or the conventional technology are introduced briefly hereinafter. Apparently, the drawings described in the following illustrate some embodiments of the present disclosure, other drawings may be obtained by those ordinarily skilled in the art based on these drawings without any creative efforts.

FIG. 1 is a schematic structural diagram of an array substrate in the conventional technology;

FIG. 2 is a schematic structural diagram of an array substrate in a first embodiment in accordance with the disclosure;

FIG. 3 is a schematic structural diagram of an array substrate in a second embodiment in accordance with the disclosure;

FIG. 4 is a schematic structural diagram of an array substrate in a third embodiment in accordance with the disclosure;

FIG. 5 is a schematic structural diagram of an array substrate in a fourth embodiment in accordance with the disclosure;

FIG. 6 is a schematic structural diagram of a display pane according to an embodiment of the present disclosure; and

FIG. 7 is a schematic flow chart of a method for manufacturing an array substrate according to an embodiment of the present disclosure.

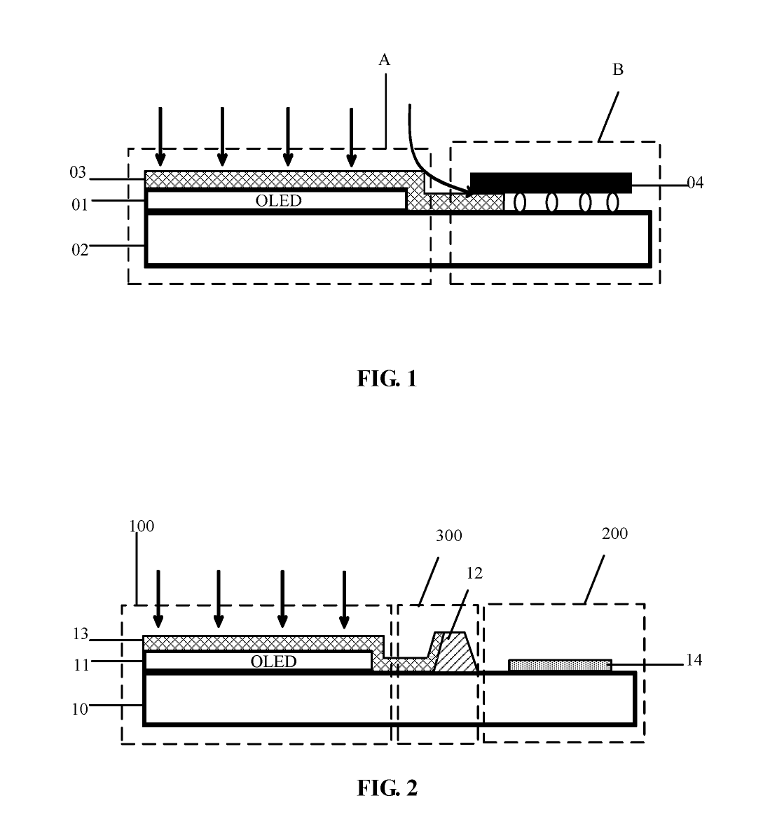

### DETAILED DESCRIPTION OF THE EMBODIMENTS

As described in the background, when the reticle 04 is placed at the location on the surface of the substrate 02 corresponding to the border region B and the protective layer 03 is then formed on the side of the OLED display unit 01 away from the substrate 02 by using the reticle 04 as a mask, there is inevitably a gap between the reticle 04 and the substrate 02. Hence, the protective layer 03 not only covers the display region A but may also extend to the border region B through the gap between the reticle 04 and the substrate 02, which can cause a negative influence on the subsequent processes such as the binding process for the circuit board.

After a lot of research, the inventors find that, main reasons for an inevitable gap between the reticle 04 and the substrate 02 include the followings: first, the surface of substrate corresponding to the border region is uneven; and secondly, when the reticle is to be placed in the border region on the surface of the substrate, a holder needs to be placed in the border region, and then the reticle is fixed on the holder with a stretching technology, hence the reticle is not under completely equal forces due to being limited by accuracy of the stretching technology, which causes a surface of the reticle toward the substrate to be uneven, and further leads to a gap between the reticle and the substrate after the reticle is placed on the substrate.

In view of this, an array substrate, including a display region, a border region surrounding the display region and a gap region located between the display region and the border region, is provided. The array substrate includes a first substrate; an OLED display unit, located on a surface of a display region on a first side of the first substrate; a barrier structure, located on a surface of a gap region on the first side of the first substrate; a protective layer covering the OLED display unit, located on the first side of the first substrate, where a boundary of the protective layer and a boundary of the barrier structure toward the display region are connected; and a circuit board, located on a surface of the border region on the first side of the first substrate.

Accordingly, a method for manufacturing an array substrate including a display region, a border region surrounding the display region and a gap region located between the display region and the border region, is provided, which includes:

providing a first substrate;

forming an OLED display unit on a surface of a display region on a first side of the first substrate;

forming a barrier structure on a surface of a gap region on the first side of the first substrate;

placing a reticle on a surface of a border region on the first side of the first substrate and a surface of the barrier structure;

forming a protective layer covering the OLED display unit on the first side of the first substrate, by using the reticle as a mask, where a boundary of the protective layer and a boundary of the barrier structure toward the display region are connected; and removing the reticle, and binding a circuit board to the surface of the border region on the first side of the first substrate.

In addition, a display panel is provided, which includes the above array substrate.

It can be seen from the array substrate, the manufacturing method thereof and the display panel including the array substrate according to the embodiments of the present disclosure that, the array substrate further includes the barrier structure located in the gap region in addition to the OLED display unit located in the display region and the circuit board located in the border region. The gap region is located between the display region and the border region. The barrier structure is located between the OLED display unit and the circuit board. Hence, when the protective layer is formed on a surface of the OLED display unit away from the first substrate by using the reticle, the barrier structure may be used to fill a gap between the reticle and the first substrate, thereby preventing the protective layer from extending to the border region, and ensuring that the protective layer is located only in the display region or partially extends to the gap region without extending to the border region. Therefore, a problem in the conventional technology that the protective layer located on the surface of the OLED display unit extends to the border region, causing a negative influence on subsequent processes such as a binding process for the circuit board, is solved.

In order to make the object, the features and the advantages of the present disclosure more clear and easy to understand, the embodiments of the present disclosure are described in detail hereinafter in conjunction with the drawings.

Specific details are described in the following descriptions, so as to fully understand the present disclosure. The present disclosure can be implemented in multiple other manners different from those described herein, similar promotions can be made by those skilled in the art without departing from the essence of the present disclosure. Hence, the present disclosure is not limited by the embodiments disclosed in the following.

An array substrate is provided according to an embodiment of the present disclosure, as shown in FIG. 2. As viewed from above, the array substrate includes a display region 100, a border region 200 surrounding the display region 100 and a gap region 300 located between the display region 100 and the border region 200. In a sectional view of the array substrate, the array substrate includes a first substrate 10; an OLED display unit 11, located on a surface of the display region 100 on a first side of the first substrate 10; a barrier structure 12, located on a surface of the gap region 300 on the first side of the first substrate 10; a protective layer 13 covering the OLED display unit 11, located on the first side of the first substrate 10, where a boundary of the protective layer 13 and a boundary of the barrier structure 12 toward the display region 100 are connected; and a circuit board 14, located on a surface of the border region 200 on the first side of the first substrate 10. The circuit board 14 may be an integrated circuit board or a flexible circuit board, which is not limited herein and depends on specific situations.

In some embodiments, a surface of the barrier structure 12 away from the first substrate 10 is flush with a surface in which a highest point of the border region 200 of the first substrate 10 is located, in a case that a surface of the first substrate 10 corresponding to the border region 200 is uneven.

It can be seen from the above that, in the array substrate in accordance with the disclosure, the protective layer 13 covers the OLED display unit 11, so as to protect the OLED display unit 11 from being affected by moisture and oxygen in air. In addition, since the boundary of the protective layer 13 and the boundary of the barrier structure 12 toward the display region 100 are connected, and the gap region 300 is located between the display region 100 and the border region 200, in the array substrate according to the embodiments of the present disclosure, the protective layer 13 will not extend to the border region 200. In this way, a problem in the conventional technology that the protective layer 13 located on the surface of the OLED display unit 11 extends to the border region 200 to cause a negative influence on subsequent processes such as a binding process for the circuit board 14, is solved.

In some embodiments, the barrier structure 12 is made of organic material. In one embodiment, the organic material is acryl. It should be noted that, in another embodiment of the present disclosure, the protective layer 13 may be a layer made of inorganic material, or a lamination of a layer made of inorganic material and a layer made of organic material, which is not limited herein as long as the protective layer is a dense protective film with a good ability to isolate moisture and oxygen.

In some embodiments, a manufacturing process for the barrier structure 12 is an inkjet printing process. In some other embodiment, the manufacturing process for the barrier structure 12 is a screen printing process, so as to strictly control a boundary of the protective layer 13 and to avoid that the protective layer 13 is formed in an unnecessary region and affects the subsequent processes, which is not limited herein. Still in some other embodiments, the manufacturing process for the barrier structure 12 can include processes other than those described above, depending on specific situations.

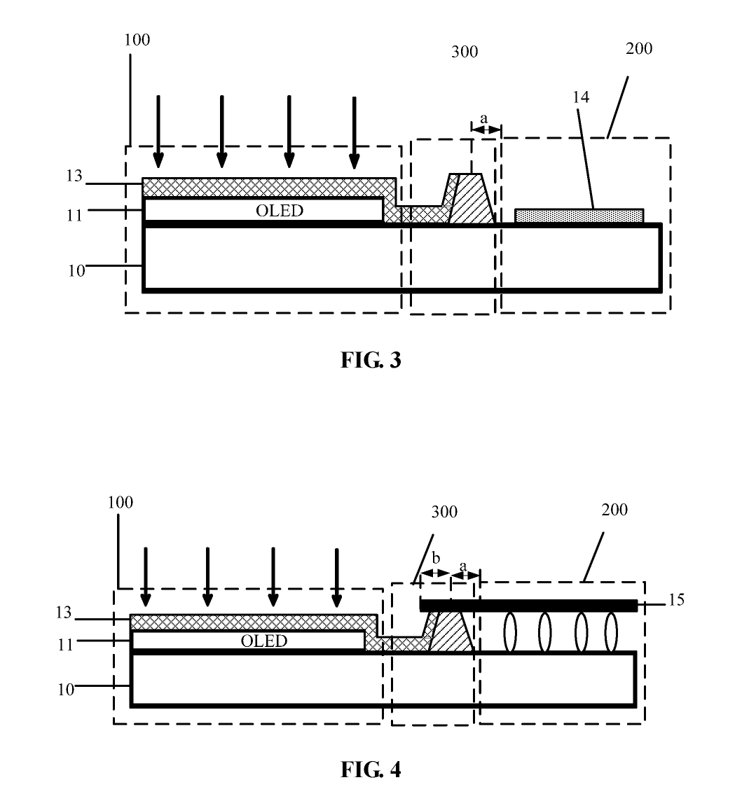

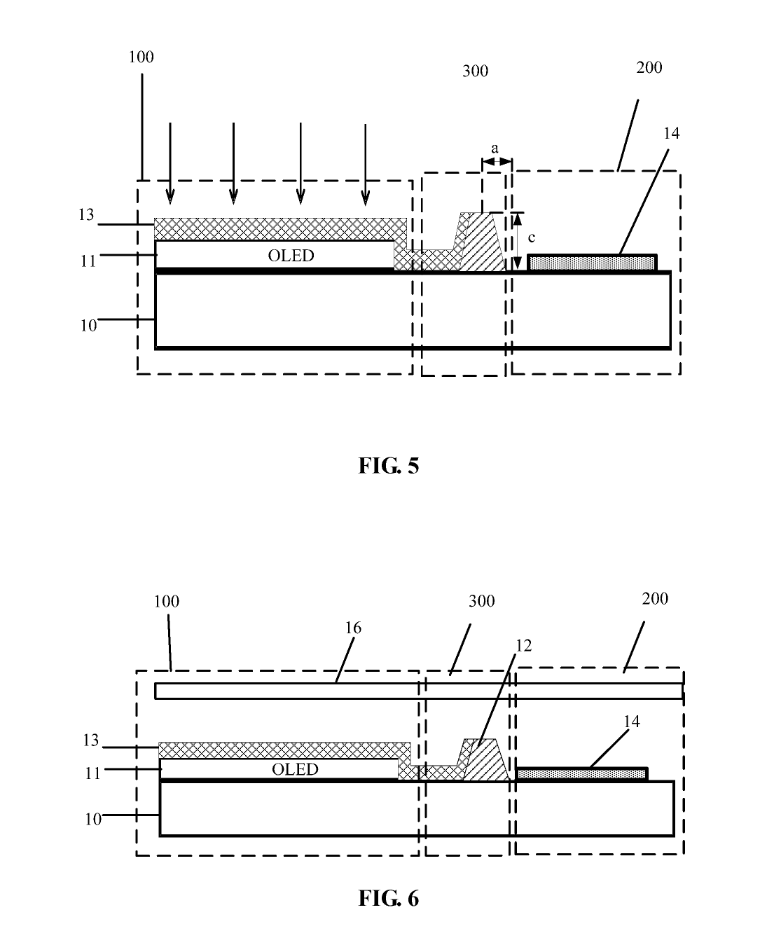

In a process of forming the barrier structure 12, it is hard to ensure that an upper surface of the barrier structure 12 is flush with a lower surface of the barrier structure 12 in a direction perpendicular to the first substrate 10. Hence, in some embodiments, a horizontal distance a between a central point of the barrier structure 12 and the border region 200 is greater than 0.3 mm, so as to ensure that the arrangement of the barrier structure 12 will not affect the binding of the circuit board 14, as shown in FIG. 3. In some other embodiments, a horizontal distance between the central point of the barrier structure 12 and a binding region for the circuit board 14 in the border region 200 is greater than 0.3 mm, so as to reduce a width of a non-display region, i.e., a sum of the border region 200 and the gap region 300, of the array substrate, on the basis of ensuring that the arrangement of the barrier structure 12 will not affect the binding of the circuit board 14.

In certain embodiments, a distance b between a boundary of a region to be covered in a process of forming the protective layer 13 toward the display region 100 and a central point of the barrier structure 12 is greater than 5μm, as shown in FIG. 4. That is, when the protective layer 13 is formed on a side of the OLED display unit 11 away from the first substrate 10 by using the reticle 15 as a mask, the distance b between the central point of the barrier structure 12 and a boundary of the reticle 15 toward the display region is greater than 5μm, so as to ensure blocking effect of the barrier structure 12.

In various embodiments, a height c of the barrier structure 12 in a direction perpendicular to a surface of the first substrate 10 ranges from 4 μm to 16 μm, inclusive, which is not limited herein as long as it is ensured that the surface of the barrier structure 12 away from the first substrate 10 is flush with a surface of the border region 200 of the first substrate 10 so as to prevent the protective layer 13 from extending to the border region 200.

In some embodiments, a projection of the barrier structure 12 completely covers a projection of the circuit board 14, in a direction from the display region 100 to the border region 200. In on specific embodiment, in a direction perpendicular to a surface of the first substrate 10, the barrier structure 12 is of closed annular shape; and in another embodiment, the barrier structure 12 may be of non-annular shape and consist of multiple partial structures, which is not limited herein as long as it is ensured that the projection of the barrier structure 12 completely covers the projection of the circuit board 14 in the direction from the display region 100 to the border region 200.

Accordingly, a display panel including the array substrate according to any one of the above embodiments is further provided according to the disclosure. As shown in FIG. 6, the display panel includes: a first substrate 10 and a second substrate 16 opposite to each other; an OLED display unit 11, located on a surface of the display region 100 on a first side of the first substrate 10; a barrier structure 12, located on a surface of the gap region 300 on the first side of the first substrate 10; a protective layer 13 covering the OLED display unit 11, located on the first side of the first substrate 10, where a boundary of the protective layer 13 and a boundary of the barrier structure 12 toward the display region 100 are connected; and a circuit board 14, located on a surface of the border region 200 on the first side of the first substrate 10. The first side of the first substrate 10 faces the second substrate 16.

In addition to the OLED display unit 11 located in the display region 100 and the circuit board 14 located in the border region 200, the array substrate and the display panel including the array substrate according to the embodiments of the present disclosure each further include the barrier structure 12 located in the gap region 300. The gap region 300 is located between the display region 100 and the border region 200. The barrier structure 12 is located between the OLED display unit 11 and the circuit board 14. Hence, when the protective layer 13 is formed on a surface of the OLED display unit 11 away from the first substrate 10 by using the reticle, the barrier structure 12 may be used to fill a gap between the reticle and the first substrate 10, thereby preventing the protective layer 13 from extending to the border region 200, and ensuring that the protective layer 13 is located only in the display region 100 or partially extends to the gap region 300 without extending to the border region 200. Therefore, a problem in the conventional technology that the protective layer 13 located on the surface of the OLED display unit 11 extends to the border region 200 to cause a negative influence on subsequent processes such as a binding process for the circuit board is solved.

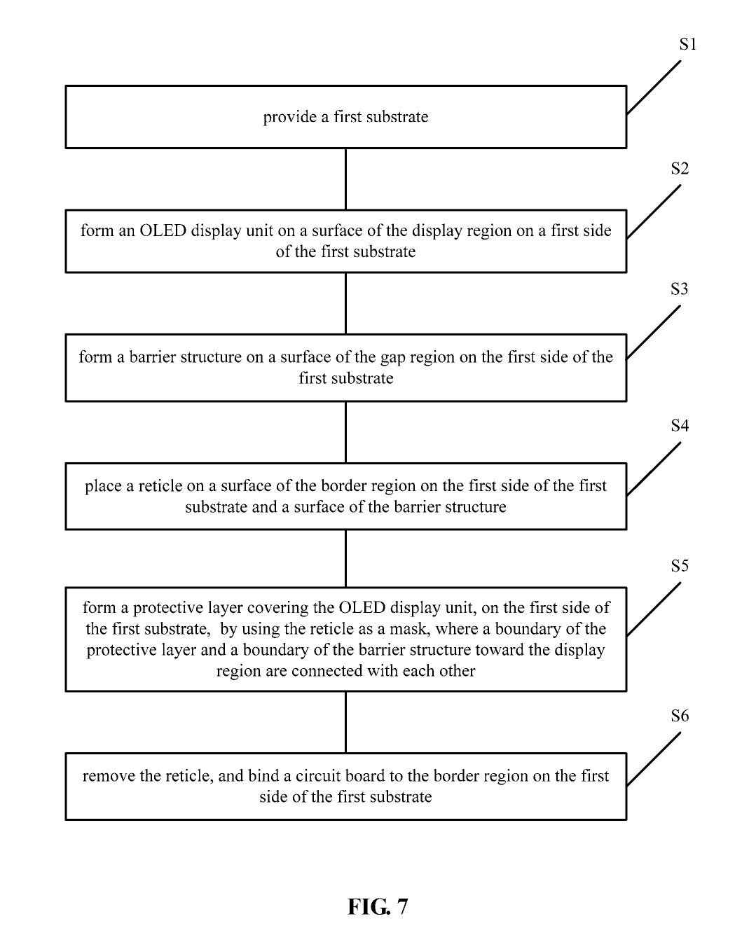

In addition, a method for manufacturing an array substrate including a display region, a border region surrounding the display region and a gap region located between the display region and the border region, is provided. As shown in FIG. 7, the method includes steps S1 to S6.

In step S1, a first substrate is provided.

In step S2, an OLED display unit is formed on a surface of the display region on a first side of the first substrate. In some embodiments, a process for forming the OLED display unit may be an evaporation process, which is not limited herein and depends on specific situations.

In step S3, a barrier structure is formed on a surface of the gap region on the first side of the first substrate.

In step S4, a reticle is placed on a surface of the border region on the first side of the first substrate and a surface of the barrier structure.

In step S5, a protective layer covering the OLED display unit is formed on the first side of the first substrate by using the reticle as a mask, where a boundary of the protective layer and a boundary of the barrier structure toward the display region are connected.

In step S6, the reticle is removed, and a circuit board is bound to the border region on the first side of the first substrate.

In some embodiments, a surface of the barrier structure away from the first substrate is optionally flush with a surface in which a highest point of the border region of the first substrate is located, in a case that a surface of the first substrate corresponding to the border region is uneven.

It can be seen that, in the method for manufacturing the array substrate according to the embodiments of the present disclosure, the barrier structure is formed on the surface of the gap region before the reticle is placed on the surface of the border region. Then when the reticle is placed on the surface of the border region, the reticle covers not only the border region but also the barrier structure in the gap region. Hence, the reticle and the barrier structure are used for blocking, in a direction from the display region to the border region, thereby avoiding that the protective layer extends to the border region when the protective layer is formed on a surface of the OLED display unit away from the first substrate by using the reticle as a mask. Therefore, a problem in the conventional technology that the protective layer located on the surface of the OLED display unit extends to the border region to cause a negative influence on subsequent processes such as a binding process for the circuit board is solved.

In some embodiments, the barrier structure is made of organic material, and the organic material is optionally acryl, which is not limited herein as long as the protective layer is a dense protective film with a good ability to isolate moisture and oxygen.

In some embodiments, a manufacturing process for the barrier structure is an inkjet printing process. In another embodiment, the manufacturing process for the barrier structure is a screen printing process, so as to strictly control a boundary of the protective layer and to avoid that the protective layer is formed in an unnecessary region and affects the subsequent processes, which is not limited herein; and in another embodiment of the present disclosure, the manufacturing process for the barrier structure may be other processes, which depend on specific situations.

In a process of forming the barrier structure, it is hard to ensure that an upper surface of the barrier structure is flush with a lower surface of the barrier structure in a direction perpendicular to the first substrate. Hence, in some embodiments, a horizontal distance between a central point of the barrier structure and the border region is greater than 0.3 mm, so as to ensure that the arrangement of the barrier structure will not affect the binding of the circuit board. Optionally, a horizontal distance between the central point of the barrier structure and a binding region for the circuit board in the border region is greater than 0.3 mm, so as to reduce a width of a non-display region, i.e., a sum of the border region and the gap region, of the array substrate, on the basis of ensuring that the arrangement of the barrier structure will not affect the binding of the circuit board.

In certain embodiments, a distance between a boundary of a region to be covered in a process of forming the protective layer toward the display region and a central point of the barrier structure is greater than 5 μm, so as to ensure blocking effect of the barrier structure.

In still some embodiments, a height of the barrier structure in a direction perpendicular to a surface of the first substrate ranges from 4 μm to 16 μm, inclusive, which is not limited herein as long as it is ensured that the surface of the barrier structure away from the first substrate is flush with a surface of the first substrate in the border region so as to prevent the protective layer from extending to the border region.

In yet some embodiments, a projection of the barrier structure completely covers a projection of the circuit board, in a direction from the display region to the border region; in an embodiment of the present disclosure, in a direction perpendicular to a surface of the first substrate, the barrier structure is of closed annular shape; and in another embodiment of the present disclosure, the barrier structure may be of non-annular shape and consist of multiple partial structures, which is not limited herein as long as it is ensured that the projection of the barrier structure completely covers the projection of the circuit board in the direction from the display region to the border region.

In conclusion, in the method for manufacturing the array substrate according to the embodiments of the present disclosure, the barrier structure is formed on the surface of the gap region before the reticle is placed on the surface of the border region. Then when the reticle is placed on the surface of the border region, the reticle covers not only the border region but also the barrier structure in the gap region. Hence, the reticle and the barrier structure are used for blocking, in a direction from the display region to the border region, thereby avoiding that the protective layer extends to the border region when the protective layer is formed on a surface of the OLED display unit away from the first substrate by using the reticle as a mask, and ensuring that the protective layer is located only in the display region or partially extends to the gap region without extending to the border region. Therefore, a problem in the conventional technology that the protective layer located on the surface of the OLED display unit extends to the border region to cause a negative influence on subsequent processes such as a binding process for the circuit board is solved.

Various embodiments are described herein in a progressive way, the differences from other embodiments are emphatically illustrated in each of the embodiments, and reference can be made to other embodiments for understanding the same or similar parts of the embodiments.

The above descriptions of the disclosed embodiments enable those skilled in the art to practice or use the present disclosure. Various changes to the embodiments are apparent to those skilled in the art, and general principles defined herein may be implemented in other embodiments without departing from the spirit or scope of the present disclosure. Hence, the present disclosure is not limited to the embodiments disclosed herein but is to conform to the widest scope consistent with the principles and novel features disclosed herein.

1. An array substrate, comprising a display region, a border region surrounding the display region and a gap region located between the display region and the border region, the array substrate comprising:
a first substrate;
an OLED display unit, located on a surface of a display region on a first side of the first substrate;
a barrier structure, located on a surface of a gap region on the first side of the first substrate;
a protective layer covering the OLED display unit, located on the first side of the first substrate, wherein a boundary of the protective layer and a boundary of the barrier structure toward the display region are connected; and
a circuit board, located on a surface of the border region on the first side of the first substrate.

2. The array substrate according to claim 1, wherein the barrier structure is made of organic material.

3. The array substrate according to claim 2, wherein the organic material is acryl.

4. The array substrate according to claim 1, wherein a horizontal distance between a central point of the barrier structure and the border region is greater than 0.3 mm.

5. The array substrate according to claim 4, wherein a horizontal distance between the central point of the barrier structure and a binding region for the circuit board in the border region is greater than 0.3 mm.

6. The array substrate according to claim 1, wherein a distance between a boundary of a region to be covered in a process of forming the protective layer toward the display region and a central point of the barrier structure is greater than 5 μm.

7. The array substrate according to claim 1, wherein a height of the barrier structure in a direction perpendicular to a surface of the first substrate ranges from 4 μm to 16 μm, inclusive.

8. The array substrate according to claim 1, wherein a projection of the barrier structure completely covers a projection of the circuit board, in a direction from the display region to the border region.

9. A display panel comprising an array substrate, wherein, the array substrate comprises a display region, a border region surrounding the display region and a gap region located between the display region and the border region, and the array substrate comprises:
a first substrate;
an OLED display unit, located on a surface of a display region on a first side of the first substrate;
a barrier structure, located on a surface of a gap region on the first side of the first substrate;
a protective layer covering the OLED display unit, located on the first side of the first substrate, wherein a boundary of the protective layer and a boundary of the barrier structure toward the display region are connected; and
a circuit board, located on a surface of the border region on the first side of the first substrate.

10. A method for manufacturing an array substrate comprising a display region, a border region surrounding the display region and a gap region located between the display region and the border region, the method comprising:
providing a first substrate;
forming an OLED display unit on a surface of a display region on a first side of the first substrate;
forming a barrier structure on a surface of a gap region on the first side of the first substrate;
placing a reticle on a surface of a border region on the first side of the first substrate and a surface of the barrier structure;
forming a protective layer covering the OLED display unit on the first side of the first substrate, by using the reticle as a mask, wherein a boundary of the protective layer and a boundary of the barrier structure toward the display region are connected;
removing the reticle; and
binding a circuit board to the surface of the border region on the first side of the first substrate.

11. The manufacturing method according to claim 10, wherein a manufacturing process for the barrier structure is an inkjet printing process or a screen printing process.

12. The manufacturing method according to claim 10, wherein a horizontal distance between a central point of the barrier structure and the border region is greater than 0.3 mm.

13. The manufacturing method according to claim 11, wherein a horizontal distance between the central point of the barrier structure and a binding region for the circuit board in the border region is greater than 0.3 mm.

14. The manufacturing method according to claim 10, wherein a distance between a boundary of the reticle toward the display region and a central point of the barrier structure is greater than 5μm.

15. The manufacturing method according to claim 10, wherein a height of the barrier structure in a direction perpendicular to a surface of the first substrate ranges from 4 μm to 16 μm, inclusive.
